(19) United States
(12) Patent Application Publication
(10) Pub. No.: US 2023/0032292 A1
(43) Pub. Date: Feb. 2, 2023

(54) METHOD FOR FORMING THIN FILM BY DEPOSITION PROCESS

(71) Applicant: CHANGXIN MEMORY TECHNOLOGIES, INC., Hefei City, (CN)

(72) Inventors: Xiaoling WANG, Hefei (CN); Zhonglei WANG, Hefei (CN); HAI-HAN HUNG, Hefei (CN); MIN-HUI CHANG, Hefei (CN)

(21) Appl. No.: 17/518,700

(22) Filed: Nov. 4, 2021

Related U.S. Application Data
(63) Continuation of application No. PCT/CN2021/117094, filed on Sep. 8, 2021.

(30) Foreign Application Priority Data
Jul. 28, 2021 (CN) 202110860037.1

(51) Int. Cl. C23C 16/455; C23C 16/06

(52) U.S. Cl. CPC C23C 16/45536; C23C 16/06; C23C 16/45544; C23C 16/45553

(57) ABSTRACT

A method for forming a thin film by a deposition process, including: a substrate is placed in a deposition chamber; a precursor is introduced into the deposition chamber to form an adsorption layer on a surface of the substrate; a reactant is introduced into the deposition chamber and reacts with the adsorption layer to form a thin film layer on the surface of the substrate and generate reaction byproducts; a vacuuming operation is performed on the deposition chamber to decrease a chamber pressure therein to reduce desorption energy of the reaction byproducts formed at the surface of the thin film layer; plasma is introduced into the deposition chamber to increase energy of the surface of the formed thin film layer; a cleaning gas is introduced into the deposition chamber to discharge the reaction byproducts and the residual precursor and reactant in the deposition chamber.

### CROSS-REFERENCE TO RELATED APPLICATIONS

The present application is a continuation application of International Application No. PCT/CN2021/117094, filed on Sep. 8, 2021, which claims priority to Chinese Patent Application No. 202110860037.1, filed on Jul. 28, 2021. The disclosures of International Application No. PCT/CN2021/117094 and Chinese Patent Application No. 202110860037.1 are hereby incorporated by reference in their entireties.

### BACKGROUND

A thin film process is a very important process in the field of semiconductor process, such as a titanium nitride (TiN) thin film served as an adhesive layer and a barrier layer of commonly used tungsten (W) in current three-dimensional flash memory type devices, which may be prepared by physical vapor deposition (PVD) process and chemical vapor deposition (such as atomic layer deposition (ALD)) process. However, since the PVD process is poor in terms of step coverage and overhang in a construction where the aspect ratio is high, the application of the TiN thin film prepared by the PVD process in the current three-dimensional flash devices is limited. A titanium nitride thin film which is prepared by the CVD process and served as an adhesive layer has a better step coverage, but the resistivity of the TiN thin film prepared by the CVD process is significantly greater than that of the TiN thin film prepared by the PVD process.

Therefore, how to improve the quality and electrical property of the thin film is still an urgent problem to be solved in the field.

### SUMMARY

The disclosure relates to the field of memory, and in particular to a method for forming a thin film by a deposition process.

In view of this, some embodiments of the disclosure provide a method for forming a thin film by a deposition process, which includes the following operations.

At S1, a substrate is placed in a deposition chamber.

At S2, a precursor is introduced into the deposition chamber to form an adsorption layer on a surface of the substrate.

At S3, a reactant is introduced into the deposition chamber and reacts with the adsorption layer to form a thin film layer on the surface of the substrate and generate reaction byproducts.

At S4, after S3 is performed, a vacuuming operation is performed on the deposition chamber to decrease a chamber pressure in the deposition chamber to reduce desorption energy of the reaction byproducts formed at the surface of the thin film layer.

At S5, plasma is introduced into the deposition chamber to increase energy of the surface of the formed thin film layer.

At S6, after S5 is performed, a cleaning gas is introduced into the deposition chamber, and the reaction byproducts and the residual precursor and reactant in the deposition chamber are discharged.

### BRIEF DESCRIPTION OF THE DRAWINGS

FIG. 1 is a schematic flowchart of forming a thin film by a deposition process of an embodiment of the disclosure.

FIG. 2 is a schematic flowchart of forming a thin film by a deposition process of another embodiment of the disclosure.

FIG. 3 is a schematic flowchart of forming a thin film by a deposition process of still another embodiment of the disclosure.

### DETAILED DESCRIPTION

As stated in the Background, the quality and electrical property of a TiN thin film formed with the existing chemical vapor deposition process are necessary to be improved.

A study has found that when the chemical vapor deposition process is employed to form the TiN thin film, a precursor is TiCl₄, a reaction gas is NH₃, and the TiN thin film is formed by gradually replacing Cl in the precursor TiCl₄ by NH₃. But this process may result in residues of Cl existed in the formed TiN thin film or at a surface thereof. Since Cl itself is easily acidified and thus is corrosive, there is a great influence on the quality and electrical property of the TiN thin film, resulting in such as an increase of the resistance, a larger leakage current or the like. Further studies have found that the residual Cl in the TiN thin film is formed after reaction byproducts (Cl and HCl) generated from the reaction between the precursor and the reactant are adsorbed at the surface of the TiN thin film. Cl and HCl have strong adsorption to the surface of the TiN thin film, so it is difficult to remove the reaction byproducts in the deposition chamber by an existing cleaning gas, so that it is hard to decrease Cl content in the TiN thin film.

Therefore, the disclosure provides a method for forming a thin film by a deposition process. S1 is performed, in which a substrate is placed in a deposition chamber. S2 is performed, in which a precursor is introduced into a deposition chamber to form an adsorption layer on a surface of the substrate, and S3 is performed, in which a reactant is introduced into the deposition chamber and reacts with the adsorption layer to form a thin film layer on the surface of the substrate, and reaction byproducts are generated. After that S4 is performed following S3, in which a vacuuming operation is performed on the deposition chamber to decrease a chamber pressure in the deposition chamber so as to reduce desorption energy of the reaction byproducts formed at a surface of the thin film layer. At S5, plasma is introduced into the deposition chamber to increase energy of the surface of the formed thin film layer. At S6, after S5 is performed, a cleaning gas is introduced into the deposition chamber, and the reaction byproducts and the residual precursor and reactant in the deposition chamber are discharged. When S3 is performed to form the thin film layer, the reaction byproducts (such as impurities of HCl and Cl) will be formed, a portion of the reaction byproducts will be adsorbed at the surface of the thin film layer with strong adsorption and strong desorption energy so that it is difficult to directly remove them by the cleaning gas. Therefore after S3 is performed, S4 will be performed, in which the vacuuming operation is performed on the deposition chamber (such as by a pump) to decrease the chamber pressure in the deposition chamber, so as to reduce desorption energy of the reaction byproducts formed at the surface of the thin film layer in S3. Moreover, the decrease in pressure of the deposition chamber means that the pumping capability of the pump will increase accordingly, so that when the vacuuming operation is performed, the portion or all of the reaction byproducts at the surface of the thin film layer may be discharged from the deposition chamber by physical desorption, which is conducive to the reduction of the impurities in the formed thin film layer, thereby increasing the quality and electrical property of the formed thin film layer, such as reducing the resistance of the thin film layer, reducing the leakage current, or the like. S5 is performed, in which the plasma is introduced to increase the energy of the surface of the thin film layer so as to avoid a situation that the byproducts fall back again and are adsorbed to the surface of the thin film layer. With purging by the cleaning gas in S6, it is further to facilitate the reaction byproducts adsorbed at the surface of the thin film layer to be discharged.

In order to make the objectives, characteristics, and advantages of the disclosure appear more clear and easy to understand, specific embodiments of the disclosure will be described below in detail in combination with the drawings. When the embodiments of the disclosure are described in detail, for the purpose of illustration, the schematic diagram will be partially amplified not in a general proportion and the schematic diagram is merely an example, which should not limit the scope of the disclosure. Furthermore, a three dimensional spatial size of length, width, and depth should be included in actual production.

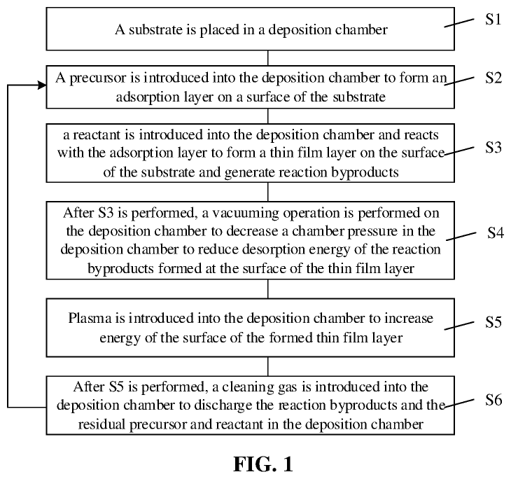

Referring to FIG. 1, an embodiment of the disclosure provides a method for forming a thin film by a deposition process, which includes the following operations.

At S1, a substrate is placed in a deposition chamber.

At S2, a precursor is introduced into the deposition chamber to form an adsorption layer on a surface of the substrate.

At S3, a reactant is introduced into the deposition chamber and reacts with the adsorption layer to form a thin film layer on the surface of the substrate and generate reaction byproducts.

At S4, after S3 is performed, a vacuuming operation is performed on the deposition chamber to decrease a chamber pressure in the deposition chamber to reduce desorption energy of the reaction byproducts formed at the surface of the thin film layer.

At S5, plasma is introduced into the deposition chamber to increase energy of the surface of the formed thin film layer.

At S6, after S5 is performed, a cleaning gas is introduced into the deposition chamber, and the reaction byproducts and the residual precursor and the reactant in the deposition chamber are discharged.

The foregoing process will be described in detail below.

S1 is performed, in which the substrate is placed in the deposition chamber.

The thin film layer is subsequently formed at the surface of the substrate by the chemical vapor deposition process. The thin film layer may be configured to serve as one or more of a conductive layer, a barrier layer, or an adhesive layer, and the thin film layer may also be configured to serve as a high K (K is larger than 2.5) dielectric layer.

In one embodiment, the material of the thin film layer may be metal nitride or metal oxide. Specifically, the material of the thin film layer subsequently formed is TiN, TiO₂, HfO₂, Al₂O₃, or ZrO₂. The TiN thin film layer may be configured to serve as one or more of the conductive layer, the barrier layer, or the adhesive layer. The TiO₂ thin film layer, the HfO₂ thin film layer, the Al₂O₃ thin film layer, or the ZrO₂ thin film layer may be configured to serve as a high K dielectric layer. In this embodiment, a case of subsequently formed thin film layer of a TiN thin film will be described as an example.

In one embodiment, the substrate may be a semiconductor substrate, a material of the semiconductor substrate may be silicon (Si), germanium (Ge), or silicon germanium (GeSi), silicon carbide (SiC); the material of the semiconductor substrate may also be silicon-on-insulator (SOD, or germanium-on-insulator (GOI), or may also be other materials, such as a III-V group compound, for example, gallium arsenide. The semiconductor substrate is doped with a certain impurity ions according to the requirement. The impurity ions may be N-type impurity ions or P-type impurity ions. In this embodiment, the material of the semiconductor substrate is silicon. The semiconductor substrate may be configured to form several trench transistors, which serve as a part of a DRAM memory device. Specifically, several discrete active areas are provided in the semiconductor substrate, the adjacent active areas are isolated by isolation layers, at least one word line trench is between each of the active areas and the adjacent isolation layer (or at least one word line trench is formed at the surface of the substrate), then a thin film layer, such as the TiN thin film layer, is formed at sidewalls and bottom surface of the word line trench by the method for forming the thin film provided by the disclosure, and after the thin film layer is formed, the word line trench is filled up with a metal, such as W, to form a buried metal word line (or a buried metal gate). The thin film layer serves as a barrier layer and a adhesive layer of the buried metal word line (or the buried metal gate).

In another embodiment, a thin film layer, such as a TiO₂ thin film layer, an HfO₂ thin film layer, an Al₂O₃ thin film layer, or a ZrO₂ thin film layer, is directly formed by the method for forming the thin film provided in the disclosure on the surface of the semiconductor. The thin film layer serves as a high K dielectric layer of a transistor. After the thin film layer is formed, a metal gate is formed on the thin film layer.

In another embodiment, the substrate may include a semiconductor substrate and an interlayer dielectric layer thereon.

The semiconductor substrate may be formed with semiconductor devices therein or at the surface thereof and the semiconductor devices may be one or two of a memory, a transistor (including a trench transistor), or may be other functional semiconductor devices.

A conductive connection structure or a capacitor connected to the semiconductor device is formed in the interlayer dielectric layer, and the conductive connection structure is one or more of a plug, a metal line or a damascus structure. In one embodiment, when the conductive connection structure is formed, an opening or a trench is formed in the interlayer dielectric layer, and a thin film layer, such as a TiN thin film layer, is formed at the sidewall and the bottom surface of the opening or the trench by employing the method for forming the thin film provided in the disclosure. Then the conductive connection structure is formed by filling up the opening or the trench with a metal. The formed thin film layer serves as a barrier layer and an adhesive layer of the conductive connection structure. In another embodiment, when a capacitor is formed, a capacitor hole is formed in the interlayer dielectric layer, a thin film layer, such as a TiN thin film layer, is formed at the sidewall and the bottom surface of the capacitor hole, which serves as a lower electrode layer of the capacitor, after the thin film layer is formed, a dielectric layer of the capacitor is formed on the thin film layer, and an upper electrode layer of the capacitor is formed on the dielectric layer.

In one embodiment, the interlayer dielectric layer may be a single layer structure or a multi-layered stack structure. The material of the bottom dielectric layer may be silicon oxide, fluorine-doped silicon glass (FSG), a low dielectric constant material, other suitable material, and/or combination thereof.

The deposition chamber is a chamber for performing the deposition process, which includes supercritical fluid deposition (SFD), atomic layer deposition (ALD), or plasma enhanced atomic layer deposition (PEALD). When the deposition process is SFD, the precursor and the reactant are introduced into the deposition chamber in the form of overcritical fluids, which have advantages of depositing successively and growing rapidly. When the deposition process is ALD, the precursor and the reactant are introduced into the deposition chamber in the form of gases. Although the film layer has a slow growth rate, it has the advantages that the thickness and the quality of the film are well controlled. When the deposition process is PEALD, the precursor and the reactant which are in the form of gases are ionized and introduced into the deposition chamber. The process has advantages of higher growth rate, better thickness control of the film layer, and lower reaction temperature.

S2 is performed, in which the precursor is introduced into the deposition chamber to form an adsorption layer at the surface of the substrate.

The precursor is for forming the adsorption layer at the surface of the substrate. The adsorption layer is reacted with the reactant that is subsequently introduced into the deposition chamber to form the thin film layer at the surface of the substrate.

The precursor may be introduced into the deposition chamber in a form of gas or overcritical fluid. Specifically, when the deposition process is ALD or PEALD, the precursor is introduced into the deposition chamber in the form of gas, when the deposition process is SFD, the precursor is introduced into the deposition chamber in the form of overcritical fluid.

In one embodiment, when the thin film layer to be formed is a TiN thin film layer or a TiO₂ thin film layer, the precursor may employ TiCl₄. In another embodiment, when the thin film layer to be formed is an HfO₂ thin film layer, the precursor may employ HfCl₄.

In one embodiment, when the precursor is introduced, the chamber pressure in the deposition chamber ranges from 2 torr to 10 torr. When the precursor is TiCl₄, the precursor has a flow of 10 sccm to 200 sccm.

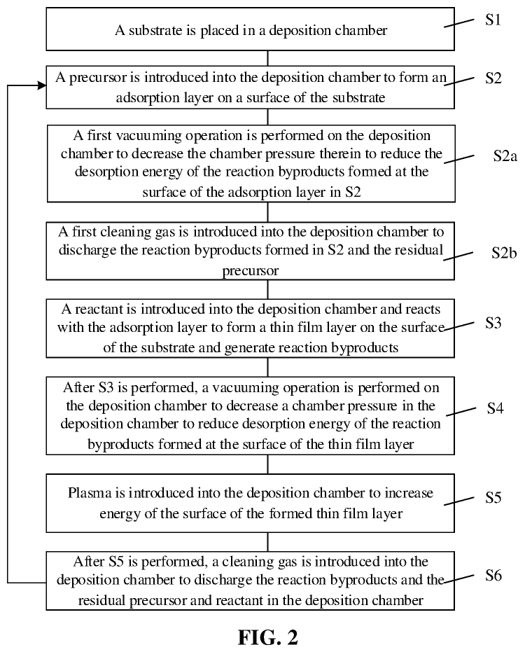

In one embodiment, when the deposition process is ALD or PEALD, after S2 is performed and before S3 is performed, S2a and S2b may be further included, the details of which are with reference to FIG. 2. After S2, S2a is performed, in which a first vacuuming operation is performed to decrease the chamber pressure in the deposition chamber so as to reduce desorption energy of the reaction byproducts formed at the surface of the adsorption layer in S2. After S2a, S2b is performed, in which a first cleaning gas is introduced into the deposition chamber to discharge the reaction byproducts and the residual precursor formed in S2.

When S2 is performed to form the adsorption layer, the reaction byproducts (such as a portion of impurity Cl separated from the precursor) will be formed. It is difficult to directly discharge, by the cleaning gas, the portion of the reaction byproducts which will be adsorbed at the surface of the adsorption layer. Therefore after S2, S2a is performed through the first vacuuming operation which is typically performed by a pump to decrease the chamber pressure in the deposition chamber thereby reducing desorption energy (the desorption energy is the energy required to cause desorption of impurities of Cl from the surface of the adsorption layer) of the reaction byproducts (the impurity Cl) formed at the surface of the adsorption layer in S2. Moreover, the decrease in pressure of the deposition chamber means that the pumping capability of the pump will increase accordingly, so that when the first vacuuming operation is performed, a portion or all of the reaction byproducts (the impurity Cl) at the surface of the adsorption layer may be discharged, by physical desorption, from the deposition chamber, which is (further) conducive to reduction of the impurities in the subsequently formed thin film layer, thereby (further) increasing the quality and electrical property of the formed thin film layer, such as reducing the resistance of the thin film layer, reducing the leakage current, or the like.

In one embodiment, when S2a is performed, the chamber pressure in the deposition chamber may range from 1 torr to 10 torr, and the first vacuuming operation time ranges from 0.1 s to 5 s.

After S2a, S2b is performed, in which the first cleaning gas is introduced into the deposition chamber, and the reaction byproducts and the residual precursor formed in the deposition chamber in S2 are discharged. Since when S2a is performed, the reaction byproducts (the impurity Cl) at the surface of the adsorption layer have been discharged, a portion of the reaction byproducts and the residual precursor in the deposition chamber will also be discharged at S2a. By performing S2b, the remaining reaction byproducts and the residual precursor in the deposition chamber are discharged from the deposition chamber.

When the first cleaning gas is introduced, the pressure in the deposition chamber will increase. In one embodiment, the pressure in the deposition chamber will increase to 2 torr to 10 torr again. The remaining reaction byproducts and the residual precursor in the deposition chamber are discharged from the deposition chamber by the first cleaning gas.

The first cleaning gas is an inert gas, which may specifically be N₂, H₂, Ar or He.

With continued reference to FIG. 1, S3 is performed, the reactant is introduced into the deposition chamber so that the reactant reacts with the adsorption layer to form the thin film layer on the surface of the substrate and generate the reaction byproducts.

The reactant is used to react with the adsorption layer to form the thin film layer on the surface of the substrate and the reaction byproducts may be generated.

The reactant may be introduced into the deposition chamber in a form of gas or overcritical fluid. Specifically, when the deposition process is ALD or PEALD, the reactant is introduced into the deposition chamber in the form of gas, when the deposition process is SFD, the reactant is introduced into the deposition chamber in the form of overcritical fluid.

In one embodiment, when the thin film layer to be formed is a TiN thin film layer or a TiO₂ thin film layer, the reactant may employ NH₃. In another embodiment, when the thin film layer to be formed is an HfO₂ thin film layer, the reactant may employ H₂O.

In one embodiment, when a reactant is introduced, the chamber pressure in the deposition chamber ranges from 2 torr to 10 torr, and when the reactant is NH₃, the reactant has a flow rate of 1000 sccm to 8000 sccm.

In this embodiment, when the reactant reacts with the adsorption layer to form a thin film layer, reaction byproducts containing Cl, such as impurities of HCl and Cl, will be formed. A portion of the reaction byproducts containing Cl will be absorbed at the surface of the thin film layer and have a strong adsorption property and high desorption energy. In other embodiments, the elements contained in the reaction byproducts may be different which depends on the species of the precursor and the reactant.

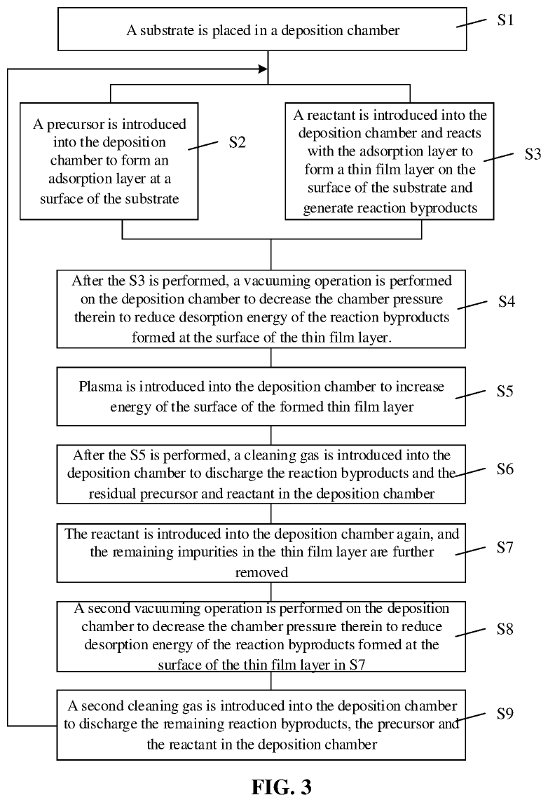

It is to be noted that in some embodiments, when the deposition process is ALD or PEALD, S3 may be performed after S2. Reference is made to FIG. 1 and FIG. 2 for the details. In other embodiments, when the deposition process is SFD, S3 may also be performed simultaneously with S2. Referring to FIG. 3, when S2 is performed, S3 is performed simultaneously.

With continued reference to FIG. 1, S4 is performed, after S3 is performed, in which the vacuuming operation is performed on the deposition chamber to decrease the chamber pressure therein so as to reduce desorption energy of the reaction byproducts formed at the surface of the thin film layer.

In an embodiment, when S4 is performed, the chamber pressure in the deposition chamber may range from 1 torr to 10 torr, and the vacuuming operation time ranges from 0.1 s to 5 s. In the above-mentioned scope, when S3 is performed to form the thin film layer, the reaction byproducts containing Cl (such as impurities of HCl and Cl) will be formed, a portion of the reaction byproducts containing Cl are adsorbed at the surface of the thin film layer and have the strong adsorption property and the high desorption energy so that it is difficult to discharge them by the cleaning gas. Therefore after S3, S4 will be performed, in which the vacuuming operation is performed on the deposition chamber (such as by a pump) to decrease the chamber pressure therein so as to reduce desorption energy (the desorption energy is the energy required to cause desorption of the impurities of HCl and Cl from the adsorption layer) of the reaction byproducts (the impurities of HCl and Cl) formed on the surface of the thin film layer in S3. Moreover, the decrease in pressure of the deposition chamber means that the pumping capability of the pump will increase accordingly, so that when the vacuuming operation is performed, a portion or all of the reaction byproducts (the impurities of HCl and Cl) at the surface of the thin film layer may be discharged, by physical desorption, from the deposition chamber, which is conducive to reduction of impurities in the formed thin film layer, thereby increasing the quality and electrical property of the formed thin film layer, such as reducing the resistance of the thin film layer, reducing the leakage current, or the like.

At S5, the plasma is introduced into the deposition chamber to increase energy of the surface of the formed film layer.

In this embodiment, S5 is performed after S4. At S5, the deposition chamber maintains the same chamber pressure as that when S4 is performed, that is, the pump keeps vacuuming.

After the energy of desorption decreases, the byproducts, such as the strongly adsorbed HCl, are desorbed from the surface of the formed thin film layer in a lower state of energy, changing from a physical adsorption state into a desorption state. At this time, plasma is introduced to increase energy of the surface of the thin film layer thereby avoiding the byproducts from falling back to be adsorbed to the surface of the thin film layer again. As stated above and described in detail below, the purge of the cleaning gas is more likely to make the reaction byproducts adsorbed on the surface of the thin film layer discharged.

In one embodiment, a process of generating the plasma that is introduced in S5 includes the following operations: providing a source gas, dissociating the source gas by a radio frequency power, forming the plasma, and introducing the plasma into the deposition chamber. In one specific embodiment, the source gas is H₂, N₂, or NH₃, the radio frequency power is 300 W to 1200 W.

S6 is performed after S5, the cleaning gas is introduced into the deposition chamber to discharge the reaction byproducts and the residual precursor and reactant therein.

When the cleaning gas is introduced, the pressure in the deposition chamber will increase. In one embodiment, the pressure in the deposition chamber increases to 2 torr to 10 torr, and the remaining reaction byproducts and the residual precursor and reactant in the deposition chamber are discharged from the deposition chamber by the cleaning gas.

The cleaning gas is an inert gas, which may specifically be N₂, H₂, Ar or He.

In an embodiment, after S6 is performed, referring to FIG. 1, the following operations are further included: S2, S3, S4, S5 and S6 are repeated so as to obtain a thin film layer with expected thickness and expected quality.

In another embodiment, when the deposition process is ALD or PEALD, referring to FIG. 2, after S6 is performed, S2, S2a, S2b, S3, S4, S5 and S6 are repeated until a thin film layer whose thickness meets process requirements is formed. A number of repetitions are set according to actual requirements for thickness.

In another embodiment, when the deposition process is SFD, referring to FIG. 3, after S6 is performed, S7 is further included, in which the reactant is introduced into the deposition chamber again to further remove the remaining impurities in the thin film layer; after S7 is performed, S8 is further included, in which a second vacuuming operation is performed on the deposition chamber to decrease the chamber pressure therein so as to reduce the desorption energy of the reaction byproducts formed at the surface of the thin film layer in S7; and after S8 is performed, S9 is further included, in which a second cleaning gas is introduced into the deposition chamber to discharge the remaining reaction byproducts, the precursor and the reactant in the deposition chamber.

When S7 is performed, the introduced reactant is NH₃, which reacts with the remaining impurities (Cl) in the thin film layer to form the reaction byproduct HCl, so that the remaining impurities in the thin film layer can be further removed.

After S7, S8 will be performed, in which the second vacuuming operation is performed on the deposition chamber (such as by a pump) to decrease the chamber pressure therein so as to reduce the desorption energy (the desorption energy is the energy required to cause desorption of the impurity HCl from the adsorption layer) of the reaction byproducts (the impurity HCl) formed on the surface of the thin film layer in S7. Moreover, the decrease in pressure of the deposition chamber means that the pumping capability of the pump will increase accordingly, so that when the vacuuming operation is performed, the portion or all of the reaction byproducts (the impurity HCl) at the surface of the thin film layer may be discharged by physical desorption from the deposition chamber, which is further conducive to reduction of the impurities in the formed thin film layer, thereby further increasing the quality and electrical property of the formed thin film layer, such as reducing the resistance of the thin film layer, reducing the leakage current, or the like.

When S9 is performed, the second cleaning gas is an inert gas, which may specifically be N₂, H₂, Ar or He.

After S6 is performed, S2, S3, S4, S5, S6, S7, S8, and S9 are repeated so as to obtain the thin film layer with expected thickness and expected quality.

Although the present disclosure has been disclosed in preferred embodiments as above, it is not used to limit the disclosure, and the above disclosed method and technical contents may all be utilized by those skilled in the art to make possible changes and modifications without departing from the spirit and scope of the disclosure. Therefore, any simple modifications, equivalent changes and modifications to the above embodiments according to the technical substance of the disclosure without departing from the scope of the disclosure are covered by the technical solutions of the disclosure.

1. A method for forming a thin film by a deposition process, comprising:
S1, placing a substrate in a deposition chamber;
S2, introducing a precursor into the deposition chamber to form an adsorption layer on a surface of the substrate;
S3, introducing a reactant into the deposition chamber and reacts with the adsorption layer to form a thin film layer on the surface of the substrate and generate reaction byproducts;
S4, after performing S3, performing a vacuuming operation on the deposition chamber to decrease a chamber pressure in the deposition chamber to reduce desorption energy of the reaction byproducts formed at the surface of the thin film layer;
S5, introducing plasma into the deposition chamber to increase energy of the surface of the formed thin film layer; and
S6, after performing S5, introducing a cleaning gas into the deposition chamber to discharge the reaction byproducts and the residual precursor and reactant in the deposition chamber.

2. The method for forming the thin film by the deposition process of claim 1, wherein, a material of the thin film layer is metal nitride or metal oxide.

3. The method for forming the thin film by the deposition process of claim 2, wherein, the precursor is a compound containing a corresponding metal element in the thin film layer.

4. The method for forming the thin film by the deposition process of claim 2, wherein, the material of the thin film layer is TiN, TiO₂, HfO₂, Al₂O₃ or ZrO₂.

5. The method for forming the thin film by the deposition process of claim 2, wherein, when S4 is performed, the vacuuming operation time ranges from 0.1 s to 5 s, and the chamber pressure in the deposition chamber ranges from 1 torr to 10 torr.

6. The method for forming the thin film by the deposition process of claim 1, wherein, when S2 and S3 are performed, the chamber pressure in the deposition chamber ranges from 2 torr to 10 torr.

7. The method for forming the thin film by the deposition process of claim 1, wherein, when a material of the thin film layer is TiN, the precursor is TiCl₄ and has a flow rate of 10 sccm to 200 sccm, the reactant is NH₃ and has a flow rate of 1000 sccm to 8000 sccm.

8. The method for forming the thin film by the deposition process of claim 1, wherein, a process of generating the plasma that is introduced in S5 comprises: providing a source gas, dissociating the source gas by a radio frequency power, forming the plasma, and introducing the plasma into the deposition chamber.

9. The method for forming the thin film by the deposition process of claim 8, wherein, the source gas is H₂, N₂ or NH₃, and the radio frequency power ranges from 300 W to 1200 W.

10. The method for forming the thin film by the deposition process of claim 1, wherein, the deposition process is supercritical fluid deposition (SFD), atomic layer deposition (ALD), or plasma-enhanced atomic layer deposition (PEALD).

11. The method for forming the thin film by the deposition process of claim 10, wherein, when the deposition process is ALD or PEALD, after S2 is performed, the method further comprises S2a, in which a first vacuuming operation is performed on the deposition chamber to decrease the chamber pressure in the deposition chamber to reduce desorption energy of the reaction byproducts formed at the surface of the adsorption layer in S2.

12. The method for forming the thin film by the deposition process of claim 11, wherein, after S2a is performed, the method further comprises S2b, in which a first cleaning gas is introduced into the deposition chamber to discharge the reaction byproducts formed in S2 and the residual precursor.

13. The method for forming the thin film by the deposition process of claim 12, wherein, S2 to S6 are performed at least once.

14. The method for forming the thin film by the deposition process of claim 10, wherein, when the deposition process is SFD, S2 and S3 are performed simultaneously, after S6 is performed, the method further comprises S7, in which the reactant is introduced into the deposition chamber again to remove the remaining impurities in the thin film layer; after S7 is performed, the method further comprises S8, in which a second vacuuming operation is performed on the deposition chamber to decrease the chamber pressure in the deposition chamber so as to reduce the desorption energy of the reaction byproduct formed at the surface of the thin film layer in S7; and after S8 is performed, the method further comprises S9, in which a second cleaning gas is introduced into the deposition chamber to discharge the remaining reaction byproducts, the precursor and the reactant in the deposition chamber.

15. The method for forming the thin film by the deposition process of claim 14, wherein, S2 to S9 are performed at least once.
